(19) United States
(12) Patent Application Publication
(10) Pub. No.: US 2026/0130269 A1
(43) Pub. Date: May 7, 2026

(54) ELECTRICAL DEVICE, METHOD FOR PRODUCING AN ELECTRICAL DEVICE

(71) Applicant: Schaeffler Technologies AG & Co. KG, Hezogenaurach (DE)

(72) Inventors: Matthias Duchrau, Heroldsberg (DE); Alexander Kuschel, Regensburg (DE)

(73) Assignee: Schaeffler Technologies AG & Co. KG, Herzogenaurach (DE)

(21) Appl. No.: 19/102,381

(22) PCT Filed: Aug. 3, 2023
(86) PCT No.: PCT/EP2023/071577

§ 371 Date: Jan. 9, 2026

(30) Foreign Application Priority Data
Aug. 9, 2022 (DE) 10 2022 208 289.3

(51) Int. Cl. H10W 74/10; H05K 1/181; H10W 70/60; H10W 90/00; H10W 90/10; H10W 90/28

(52) U.S. Cl. CPC H10W 74/114; H05K 1/181; H10W 70/611; H10W 90/10; H10W 90/28; H05K 2201/0275; H10W 90/752; H10W 90/755

(57) ABSTRACT

An electrical device having a component which is at least partially covered with a gel, and a printed circuit board having an end face, on which a metal layer is applied, which metal layer covers the end face at least partially. The metal layer is at least partially covered by the gel, and the metal layer physically insulates the end face from the gel completely.

### CROSS-REFERENCE TO RELATED APPLICATIONS

This application claims priority to PCT Application PCT/EP 2023/071577, filed Aug. 3, 2023, which claims priority to German Patent Application No. DE 10 2022 208 289.3, filed Aug. 9, 2022. The disclosures of the above applications are incorporated herein by reference.

### FIELD OF THE INVENTION

The present invention relates to an electric (power) device, such as e.g. (power) inverter, (power) DC-to-DC voltage converter, such as for an electrically driven motor vehicle. Furthermore, the invention relates to a method for producing a device of this type.

### BACKGROUND OF THE INVENTION

Electric (power) devices, such as e.g. (power) inverters, (power) DC-to-DC voltage converters, are known and are used inter alia in electric drives, such as for electrically driven motor vehicles. Devices of this type, owing to the fields of use thereof, e.g. in motor vehicles, are exposed to strong environmental influences, such as e.g. strong temperature change influences.

As is usual with all technical devices, there is also the general requirement for the abovementioned devices to be highly reliable.

The object of the present application is therefore to increase the reliability of the abovementioned device.

### SUMMARY OF THE INVENTION

This object is achieved by the subject matter described.

According to a first aspect of the invention, an electrical device, such as an electric power device, is provided, specifically for an electrically driven motor vehicle.

The device has a component (or a circuit component) which is at least partially, and may be completely, covered, or sealed, with a gel. Here, the gel protects the component from environmental influences and voltage flashovers.

The device further has a printed circuit board (or a plastic-based circuit carrier) which has an end face (which is not or cannot be populated). A metal layer is applied on the end face of the printed circuit board, which metal layer covers the end face at least partially, or completely. The metal layer is at least partially, or completely, covered by the gel. In this case, the metal layer physically insulates or separates the end face from the gel completely, so that the end face is not in direct physical contact with the gel or does not (not even at least partially) come into contact directly (that is to say without the metal layer lying therebetween) with the gel.

The printed circuit board has an end face which is located facing the gel and is provided with a metal layer as an edge metallization. The end face of the printed circuit board is one of the (cut) sides or side faces of the printed circuit board, which is not or cannot be populated.

The gel, which primarily covers the component (which is not the previously mentioned printed circuit board) of the device and thus seals the same, reaches as far as the metal layer and covers the same at least partially.

The metal layer insulates or separates the end face of the printed circuit board and also the printed circuit board from the gel and is used as a barrier between the gel on the one hand and the end face of the printed circuit board or the printed circuit board on the other hand and thus prevents physical contact between the gel on the one hand and the end face of the printed circuit board.

Degassings of the printed circuit board—for example at the end face thereof, which may occur in the event of a direct physical contact with the gel and under temperature change influences and may influence required requirements with respect to high voltage endurance and protection from other environmental influences—are effectively suppressed by the arrangement of the metal layer on the end face of the printed circuit board and physical insulation of the end face of the printed circuit board from the gel that has taken place as a result. The end face of the printed circuit board no longer contributes to the degassing of the printed circuit board thanks to the edge metallization with the metal layer.

Therefore, one possibility is provided for configuring the abovementioned device to be more stable with respect to the temperature change influences and thus for increasing the reliability of the device as a whole.

The component may be an electronic module or a power electronics module, such as a switchable half bridge, or a part of this module, or an electronic or power electronics component, such as an unhoused or housing-less and therefore bare semiconductor switch or power semiconductor switch of the device, which should be protected from environmental influences, such as e.g. from the moisture.

The printed circuit board may in this case be a printed circuit board with fiber-reinforced plastic.

A driver/control circuit for operating and/or for controlling the component may be formed on the printed circuit board, wherein the component may be formed as a (power) electronics module or a (power) semiconductor switch.

For example, the printed circuit board has at least one electrical conductor track. In this case, the metal layer is applied to the end face of the printed circuit board in the same metallization process of the conductor track, in which process the conductor track is applied to the printed circuit board. In this case, the same production processes in the metallization process of the conductor track is used for applying the metal layer to the end face.

The metal layer may be a metal layer that is galvanically deposited on the end face or may be applied to the end face by galvanic deposition of a metal.

Alternatively, the metal layer may be formed as a metal plate, such as e.g. a metal punched part which is applied for example by a materially bonded connection to the end face, such as e.g. adhesively bonded, soldered or sintered onto the end face.

The gel may be a sealing gel for the airtight sealing of the component or a silicone gel.

In an embodiment, the fill height of the gel does not exceed the overall height of the top edge of the metal layer. That is to say, as viewed from the plane of the bottom side of the device, the gel is filled up to a maximum fill height (from the plane of the bottom side), which the overall height (from the plane of the bottom side) of the top edge of the metal layer does not exceed.

For example, the component and the printed circuit board are arranged offset with respect to one another in the longitudinal direction of the device or arranged in rows. Accordingly, the printed circuit board is placed laterally offset with respect to the component or its section, which component or which section is covered with the gel. Therefore, the printed circuit board and the gel (or at least a part thereof) are likewise arranged in rows in the longitudinal direction of the device.

Alternatively, the printed circuit board may be formed to surround the component at least partially. A plurality of printed circuit boards and/or a plurality of components may also be provided, which may be formed or arranged to surround the component or the components.

The device may be formed as a (power) inverter or a (power) DC-to-DC voltage converter. In this case, the component may be formed as a power electronics module of the device or a part thereof. Accordingly, a driver/control circuit or a part thereof may be formed on the printed circuit board for operating and/or for controlling the power electronics module.

Due to the use of the metal layer as the edge metallization, the printed circuit board or the driver/control circuit may be positioned close to the component or the power electronics module. Parasitic inductances in electrical connections between the printed circuit board or the driver/control circuit on the one hand and the component or the power electronics module on the other hand may be kept low, which leads to an improvement of the controllability of the component or the power electronics module and thus entails an additional increase of the reliability of the device.

According to a second aspect of the invention, a method for producing a previously described device is provided, which device has a (circuit) component and a printed circuit board (or a plastic-based circuit carrier).

According to the method, a metal layer is applied to an end face of the printed circuit board, wherein the metal layer covers the end face at least partially, or completely.

Subsequently, the component is covered or sealed at least partially, or completely, with a gel by applying the gel onto the same. In this case, the gel is applied in such a manner that it at least partially covers the metal layer and at the same time is physically insulated or separated from the end face of the printed circuit board completely by the metal layer, so that the end face is not (not even at least partially) directly covered by the gel without the metal layer lying therebetween.

Various configurations of the device described above are, insofar as they are otherwise transferable to the method mentioned above, also to be regarded as possible configurations of the method.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

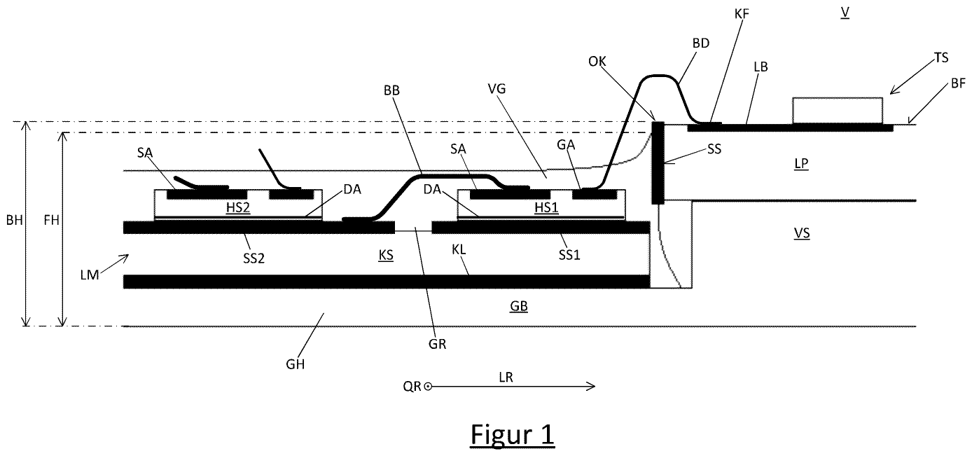

An exemplary embodiment of the invention is explained in greater detail below with reference to the accompanying drawing, namely FIG. 1.

### DETAILED DESCRIPTION OF THE PREFERRED EMBODIMENTS

The following description of the preferred embodiment(s) is merely exemplary in nature and is in no way intended to limit the invention, its application, or uses.

FIG. 1 shows a section of a device V according to an exemplary embodiment of the invention in a first schematic cross-sectional illustration.

The device V is formed in this embodiment as a power inverter of an electric drive of a motor vehicle and has a housing GH, a group of a plurality of, for example three or six, power electronics modules LM and a printed circuit board LP.

The housing GH is for example formed from aluminum or an aluminum alloy and is also used as a cooler for cooling the device V. The power electronics modules LM and the printed circuit board LP are arranged in the housing GH, wherein the printed circuit board LP is arranged on a projection VS that is shaped at the housing base GB, higher than the power electronics modules LM. In this case, the power electronics modules LM are arranged in rows in a transverse direction QR (which is transverse to the longitudinal direction LR of the device V) of the device V or the housing GH. The power-electronics-module group LM and the printed circuit board LP are in turn arranged in rows in the longitudinal direction LR. Alternatively, the printed circuit board LP may be formed such that it at least partially surrounds the power-electronics-module group LM, wherein in this case, the power electronics modules LM are arranged in a cavity that is at least partially bordered by the printed circuit board LP. Alternatively, a plurality of printed circuit boards may also be provided, which are arranged surrounding the power-electronics-module group LM.

The printed circuit board LP is for example formed with a fiber-reinforced plastic as insulating material and rests by its underside on the projection VS and is physically and thermally connected to the housing GH. On the upper side that faces away from the underside, the printed circuit board LP has a populated area BF on which a driver/control circuit TS for operating or for controlling the power electronics modules LM or a part of a circuit TS of this type, such as e.g. one or more driver resistors (such as e.g. gate resistors) for operating the power electronics modules LM, is formed or mounted. On the populated area BF, the printed circuit board LP further has one or more conductor tracks LB as a part of the circuit TS or as electrical connections to the circuit TS, which in turn in each case have one or more contact surfaces KF for producing electrical (signal) connections to the power electronics modules LM. On an end face SS that faces the power electronics modules LM and that adjoins the underside and upper side, the printed circuit board LP has a metal layer MS made from copper or a copper alloy which is for example adhesively bonded onto the end face SS as a thin metal punched part. Alternatively, the metal layer MS may be applied onto the end face SS by galvanic deposition. The metal layer MS may be applied to the end face SS in the same metallization process of the conductor track LB. The metal layer MS covers the end face SS completely or virtually completely.

Switchable half bridges of a switchable bridge circuit are formed on the power electronics modules LM. In this case, the power electronics modules LM in each case have a ceramic substrate KS, for example a DBC or an AMB substrate, which in turn in each case have a metallic cooling layer KL on their respective underside and rest by the same on the housing base GB and are physically and thermally connected to the same. The power electronics modules LM in each case have two metallic busbars SS1, SS2 on upper sides of the respective ceramic substrates KS, which are physically separated and thus electrically insulated from one another by a trench GR that extends transversely through the respective ceramic substrate KS in each case.

The power electronics modules LM in each case have two unhoused power semiconductor switches HS1, HS2 which are formed in this embodiment as SiC MOSFETs (silicon carbide metal oxide semiconductor field effect transistors). First semiconductor switches HS1 of the respective power electronics modules LM are in each case located by their respective drain connections DA at the base to respective first busbars SS1 of the same power electronics modules LM and are electrically connected to the same. Analogously, second semiconductor switches HS2 of the respective power electronics modules LM are in each case located by their respective drain connections DA at the base to respective second busbars SS2 of the same power electronics modules LM and are electrically connected to the same. By use of respective top source connections SA, the first semiconductor switches HS1 are in each case electrically connected by a bonding band BB to the respective second busbars SS2 of the same power electronics modules LM. By use of respective gate connections GA at the top, the first semiconductor switches HS1 are in each case electrically connected via a bonding wire BD to respective corresponding contact surfaces KF on the printed circuit board LP.

The device V further has a silicone gel VG or a sealing gel which is applied to the power electronics modules LM. The silicone gel VG fills intermediate spaces between the power electronics modules LM and intermediate spaces between the power electronics modules LM on the one hand and the printed circuit board LP on the other hand and covers or seals the power electronics modules LM completely or virtually completely and thus protects the power electronics modules LM from environmental influences and voltage flashovers. In this case, the silicone gel VG reaches up to the metal layer MS of the printed circuit board LP and partially covers the metal layer MS, wherein the metal layer MS physically insulates or separates the end face SS of the printed circuit board LP and therefore also the printed circuit board LP from the silicone gel VG completely. Therefore, the metal layer MS is used as a barrier between the silicone gel VG and the end face SS of the printed circuit board LP or the printed circuit board LP and prevents a direct physical contact between the silicone gel VG and the end face SS. So that the barrier due to the metal layer MS is not overcome, the silicone gel VG is filled up to a maximum fill height FH that does not exceed the overall height BH of the top edge OK of the metal layer MS. Thanks to the barrier due to the metal layer MS, possible degassing of the printed circuit board LP, which is caused by temperature change influences for example, is effectively suppressed at the end face SS thereof.

Due to the use of the edge metallization with the metal layer MS, the printed circuit board LP is positioned very close to the power electronics modules LM without this or the end face SS thereof being in direct contact with the silicone gel VG. As a result, the electrical connections or the bonding wires BD between the power electronics modules LM on the one hand and the printed circuit board LP on the other hand are kept very short, as a result of which in turn parasitic inductances in these electrical connections may be kept low, which leads to an improved controllability of the power electronics modules LM or the power semiconductor switches HS1, HS2 and thus increases the reliability thereof.

The production of the above-described device V takes place inter alia for example as described below:
First, the metal layer MS is applied to the end face SS of the printed circuit board LP. The printed circuit board LP with the metal layer MS is then mounted on the projection VS of the housing GH. Subsequently, the power electronics modules LM, which are for example mounted on the housing base GB prior to the printed circuit board LP, are sealed with the silicone gel VG. In this case, the silicone gel VG is filled up to a fill height FH that is located below the overall height BH of the top edge OK of the metal layer MS. In this case, the silicone gel VG fills intermediate spaces between the power electronics modules LM and the printed circuit board LP and reaches up to the metal layer MS of the printed circuit board LP and covers the same. The metal layer MS in this case physically separates the end face SS of the printed circuit board LP from the silicone gel VG completely.

The description of the invention is merely exemplary in nature and, thus, variations that do not depart from the gist of the invention are intended to be within the scope of the invention. Such variations are not to be regarded as a departure from the spirit and scope of the invention.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. An electrical device (V). having:
a gel;
a component (LM) which is at least partially covered with the gel (VG);
a printed circuit board (LP), further comprising:
an end face (SS), on which a metal layer is applied, which metal layer covers the end face (SS) at least partially;
wherein the metal layer (MS) is at least partially covered by the gel (VG), and the metal layer (MS) physically insulates the end face (SS) from the gel (VG) completely.

16. The electrical device (V) of claim 1, wherein the component (LM) is an electronics module or an electronic component.

17. The electrical device (V) of claim 1, wherein the printed circuit board (LP) is a printed circuit board with fiber-reinforced plastic.

18. The electrical device (V) of claim 1, further comprising:
a driver/control circuit (TS) is formed on the printed circuit board (LP);
wherein the driver/control circuit operates and/or controls the component (LM).

19. The electrical device (V) of claim 1, the printed circuit board (LP) further comprising:
at least one electrical conductor track (LB);
wherein the metal layer (MS) is applied to the end face (SS) in the same metallization process of the at least one electrical conductor track (LB).

20. The electrical device (V) of claim 1, wherein the metal layer (MS) is galvanically deposited on the end face (SS).

21. The electrical device (V) of claim 1, wherein the metal layer (MS) is formed as a metal plate.

22. The electrical device (V) of claim 7, wherein the metal plate is applied by a materially bonded connection to the end face (SS).

23. The electrical device (V) of claim 1, wherein the gel (VG) is a sealing gel for the airtight sealing of the component (LM) or a silicone gel.

24. The electrical device (V) of claim 1, wherein the fill height (FH) of the gel (VG) is less than the overall height (BH) of the top edge (OK) of the metal layer (MS).

25. The electrical device (V) of claim 1, wherein the component (LM) and the printed circuit board (LP) are arranged offset with respect to one another in the longitudinal direction (LR) of the device (V).

26. The electrical device (V) of claim 1, wherein the component (LM) and the printed circuit board (LP) are arranged in rows.

27. The electrical device (V) of claim 1, wherein the printed circuit board (LP) is formed to surround the component (LM) at least partially.

28. The electrical device (V) of claim 1, further comprising:
a driver/control circuit;
wherein the electrical device is formed as an inverter or a DC-to-DC voltage converter;
wherein the component (LM) is a power electronics module;
wherein the driver/control circuit operates and/or for controls the power electronics module and is formed on the printed circuit board (LP).

29. A method for producing a device (V) of claim 1, comprising the steps of:
applying a metal layer (MS) to an end face (SS) of a printed circuit board (LP), wherein the metal layer (MS) covers the end face (SS) at least partially;
covering a component (LM) at least partially with a gel (VG) by applying the gel (VG) onto the component (LM);
wherein the gel (VG) is applied in such a manner that the gel (VG) at least partially covers the metal layer (MS) and at the same time is physically insulated from the end face (SS) of the printed circuit board (LP) completely by the metal layer (MS).
